(19) United States
(12) Patent Application Publication
(10) Pub. No.: US 2026/0088113 A1
(43) Pub. Date: Mar. 26, 2026

(54) SEMICONDUCTOR DEVICE, PROGRAMMING METHOD THEREOF AND DATA STORAGE SYSTEM

(71) Applicant: Samsung Electronics Co., Ltd., Suwon-si (KR)

(72) Inventors: Sangbeen YOU, Suwon-si (KR); Yonghyuk CHOI, Suwon-si (KR); Doohyun KIM, Suwon-si (KR); Seung-Bum KIM, Suwon-si (KR)

(21) Appl. No.: 19/326,856

(22) Filed: Sep. 12, 2025

(30) Foreign Application Priority Data
Sep. 20, 2024 (KR) 10-2024-0127323

(51) Int. Cl. G11C 16/34; G11C 16/08; G11C 16/10

(52) U.S. Cl. CPC G11C 16/3495; G11C 16/08; G11C 16/102

(57) ABSTRACT

A semiconductor device includes a string array including a plurality of cell strings connected in parallel to a bit line, a plurality of ground select transistors included in each of the plurality of cell strings, stacked in a first direction and connected in series with each other, and a plurality of ground select lines extending in a second direction intersecting the first direction and configured to control the plurality of ground select transistors. Each of the plurality of ground select lines is commonly connected to a ground select transistor located at a corresponding height level with respect to an upper surface of a substrate among the plurality of ground select transistors, and each particular ground select transistor of the plurality of ground select transistors has a particular threshold voltage that depends on a first characteristic of the cell string in which of the particular ground select transistor is included.

### CROSS-REFERENCE TO RELATED APPLICATIONS

This application claims the priority to Korean Patent Application No. 10-2024-0127323, filed on Sep. 20, 2024, in the Korean Intellectual Property Office, the disclosure of which is incorporated herein by reference in its entirety.

### BACKGROUND

### 1. Field of the Invention

Example embodiments relate to a semiconductor device, a programming method of the semiconductor device and a data storage system.

### 2. Description of the Related Art

In response to consumer demand for the improved performance and reduced size of electronic systems that store data, the integration of semiconductor devices is increasing. Accordingly, increased sophistication in semiconductor processes and designs is desired, and specifically, design technology is desired to ensure not only reliability and performance of high-density semiconductor devices but also efficient operation.

### SUMMARY

An aspect provides a semiconductor device that is programmed based on degradation characteristics of memory cells, a programming method of the semiconductor device that uses the degradation characteristics of memory cells for programming, and a data storage system including the semiconductor device.

The technical tasks to be achieved by the present example embodiments are not limited to the technical tasks described above, and other technical tasks may be inferred from the following example embodiments.

According to an aspect, a semiconductor device includes a string array including a plurality of cell strings that are connected in parallel to a bit line, a plurality of ground select transistors that are included in each of the plurality of cell strings, stacked in a first direction and connected in series with each other, and a plurality of ground select lines that extend in a second direction intersecting the first direction and are configured to control the plurality of ground select transistors. Each of the plurality of ground select lines is commonly connected to a ground select transistor located at a corresponding height level with respect to an upper surface of a substrate among the plurality of ground select transistors, and each particular ground select transistor of the plurality of ground select transistors has a particular threshold voltage that depends on a first characteristic of the cell string in which the particular ground select transistor is included.

According to an aspect, a programming method of a semiconductor device includes grouping a plurality of ground select transistors included in a plurality of cell strings and forming sets of ground select transistors connected in series with each other into two or more groups, determining a state to which to set each of the plurality of ground select transistors based on a result of the grouping, and programming at least a portion of the plurality of ground select transistors to result in the determined states. Determining includes determining the state of each of the plurality of ground select transistors based on a first characteristic of the cell strings into which each of the plurality of ground select transistors is included.

According to an aspect, a data storage system includes a substrate, a semiconductor device on the substrate, and a peripheral circuit that is electrically connected to the semiconductor device and configured to perform a program operation for the semiconductor device, wherein the semiconductor device includes a plurality of memory cell devices and a plurality of ground select transistors that are included in each of a plurality of cell strings, which are connected in parallel to a bit line, stacked in a first direction and connected in series with each other, a plurality of word lines that extend in a second direction intersecting the first direction and are configured to control the plurality of memory cell devices, and a plurality of ground select lines that extend in the second direction and are configured to control the plurality of ground select transistors, wherein the plurality of memory cell devices are included in a main word line region configured to store data, the plurality of ground select transistors are included in a sub word line region that is configured to control access to the main word line region according to a threshold voltage that is set for each ground select transistor, each of the plurality of ground select lines is commonly connected to a set of ground select transistors located at a corresponding height level with respect to an upper surface of a substrate among the plurality of ground select transistors, and the peripheral circuit is configured to program a threshold voltage of each of the plurality of ground select transistors based on to which first ground select line each of the plurality of ground select transistors is connected.

Additional aspects of example embodiments will be set forth in part in the description which follows and, in part, will be apparent from the description, or may be learned by practice of the disclosure.

According to example embodiments, it is possible to provide a semiconductor design method by which the degradation characteristics of a memory cell is reduced. Further, according to example embodiments, it is possible to provide a semiconductor design method by which uniform degradation of memory cells is guaranteed.

Effects of the present disclosure are not limited to those described above, and other effects may be made apparent to those skilled in the art from the following description.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 and FIG. 2 are drawings illustrating a data storage system according to an example embodiment;

FIG. 3 is a drawing for explaining a cell array of a semiconductor device according to an example embodiment;

FIG. 4 is a circuit diagram illustrating a plurality of cell strings according to an example embodiment;

FIG. 5 is a plan view illustrating a semiconductor device according to an example embodiment;

FIG. 6 to FIG. 9 are drawings for explaining a method of setting a threshold voltage of a ground select transistor according to an example embodiment;

FIG. 10 is a diagram illustrating a data storage system according to an example embodiment; and

FIG. 11 is a flowchart of a programming method for a semiconductor device according to an example embodiment.

### DETAILED DESCRIPTION

Terms used in the example embodiments are selected from currently widely used general terms when possible while considering the functions in the present disclosure. However, the terms may vary depending on the intention or preference of a person skilled in the art, the emergence of new technology, and the like. Further, in certain cases, there may be terms arbitrarily selected by the applicant, and in the cases, the meaning will be described in detail in the corresponding descriptions. Therefore, where applicable, the terms used in the present disclosure should be defined based on the meaning of the terms and the contents of the present disclosure, rather than the simple names of the terms.

Throughout the specification, when a part is described as “comprising or including” a component, it does not exclude another component but may further include another component unless otherwise stated. Furthermore, terms such as “ . . . unit,” “ . . . group,” and “ . . . module” described in the specification, unless the context indicates otherwise, mean a component that processes at least one function or operation, which may be implemented as hardware, software, or a combination thereof.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Hereinafter, example embodiments of the present invention will be described in detail with reference to the accompanying drawings so that those of ordinary skill in the art to which the present disclosure pertains may easily implement them. However, the present invention may be implemented in multiple different forms and is not limited to the example embodiments described herein.

Hereinafter, example embodiments will be described in detail with reference to the drawings.

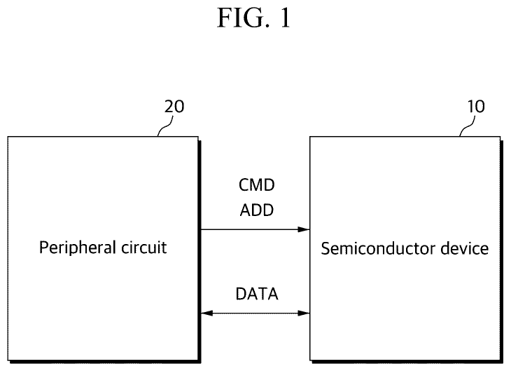

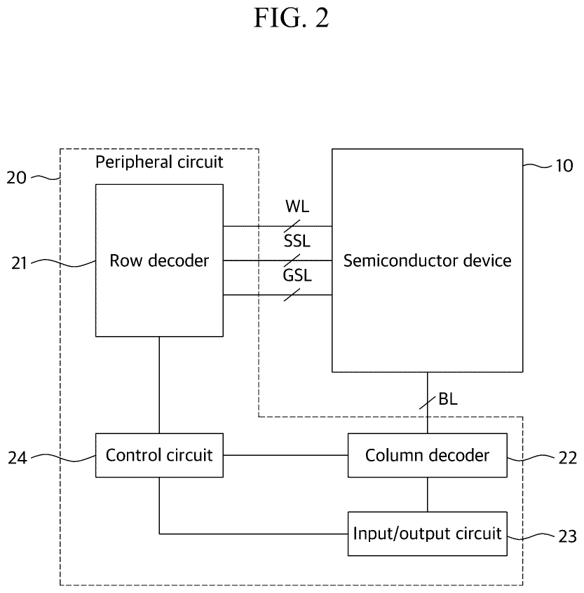

FIG. 1 and FIG. 2 are drawings illustrating a data storage system according to an example embodiment.

Referring to FIG. 1, the data storage system includes a semiconductor device 10 in which data is stored and a peripheral circuit 20 for controlling the semiconductor device 10.

The semiconductor device 10 performs program, read or erase operations in response to a command CMD and an address ADD. The semiconductor device 10 may be in the form of a semiconductor chip formed on a die from a wafer, or a semiconductor package including one or more such semiconductor chips formed on a package substrate. For example, the semiconductor device 10 (e.g., semiconductor chip or package) may include double data rate synchronous dynamic random access memory (DDR SDRAM), Low Power Double Data Rate4 (LPDDR4) SDRAM, graphics double data rate (GDDR) SDRAM, low power DDR (LPDDR), rambus dynamic random access memory (RDRAM), or FLASH Memory. Here, the flash memory may include NAND flash memory.

The peripheral circuit 20 may control the operation of the semiconductor device 10. Specifically, the peripheral circuit 20 may perform program, read, or erase operations on the semiconductor device 10. Further, the peripheral circuit 20 may transmit the command CMD, the address ADD, and data DATA, etc. to the semiconductor device 10 in response to a command received from an external device to control the semiconductor device 10, or receive the data DATA from the semiconductor device 10. Here, the address ADD may include a row address and a column address. The peripheral circuit 20 may be formed on the same semiconductor chip or package as the semiconductor device 10, or may be formed on a separate semiconductor chip or package. For example, the peripheral circuit 20 may be part of a controller chip. The peripheral circuit 20 and semiconductor device 10 may therefore together be part of a semiconductor package, or may be part of a semiconductor module (e.g., memory module), for example including one or more semiconductor packages formed on a printed circuit board.

Referring to FIG. 2, the peripheral circuit 20 may include a row decoder 21, a column decoder 22, an input/output circuit 23 and a control circuit 24, and perform control over multiple transistors included in the semiconductor device 10. In one embodiment, a plurality of transistors may be arranged three-dimensionally, and at least one of the plurality of transistors may be connected to at least some of a word line WL, a string select line SSL, and a ground select line GSL included in the semiconductor device 10. Here, local lines electrically connecting components included in the semiconductor device 10 are not limited to the word line WL, the string select line SSL and the ground select line GSL, and the local lines are disclosed as examples only of components described for understanding the present disclosure for convenience of explanation.

The row decoder 21 decodes the row address that is input from outside (e.g., from outside the semiconductor chip, package, or module that includes the peripheral circuit 20 and semiconductor device 10), and delivers voltage to the local lines (the word line WL, the string select line SSL and the ground select line GSL) corresponding to the row address. Here, the peripheral circuit 20 may further include a voltage generator (not illustrated) that generates a voltage (for example, program voltage, read voltage and erase voltage) used for the internal operation of the semiconductor device 10 under the control of the control circuit 24.

As described above, the local lines include the word line WL, the string select line SSL and the ground select line GSL, and the local lines may further include a common source line, a source select line, a drain select line and a dummy source select line.

The column decoder 22 may be connected to the semiconductor device 10 via bit lines BL. The column decoder 22 may decode an externally input column address and transmit and receive data through the bit lines BL corresponding to the column address.

The input/output circuit 23 may provide a data transmission path through which data, commands, addresses, and other signals generated from the semiconductor device 10 and the peripheral circuit 20 are exchanged with an external device.

The control circuit 24 may program data into the semiconductor device 10 based on command, address, and control signals, and the control circuit 24 may output various control signals (for example, a voltage control signal, a row address, and a column address) for reading data from multiple transistors of the semiconductor device 10. The control circuit 24 may regulate the level of voltage generated from the voltage generator (not illustrated).

In an example embodiment, each of a plurality of transistors may include a data storage element. Further, the plurality of transistors may include a plurality of memory cell devices and a plurality of ground select transistors. Here, the plurality of memory cell devices and a plurality of ground select transistors may have the same structure, but may be distinguished based on their function within the semiconductor device 10.

The semiconductor device 10 may include a cell array having a plurality of transistors arranged therein. The cell array may include a main word line region that is configured to store data and a sub word line region that is configured to control access to the main word lines. Here, a plurality of memory cell devices are included in the main word line region, a threshold voltage is set for each of the plurality of ground select transistors, and a plurality of ground select transistors may be included in the sub word line region that controls access to the main word line region.

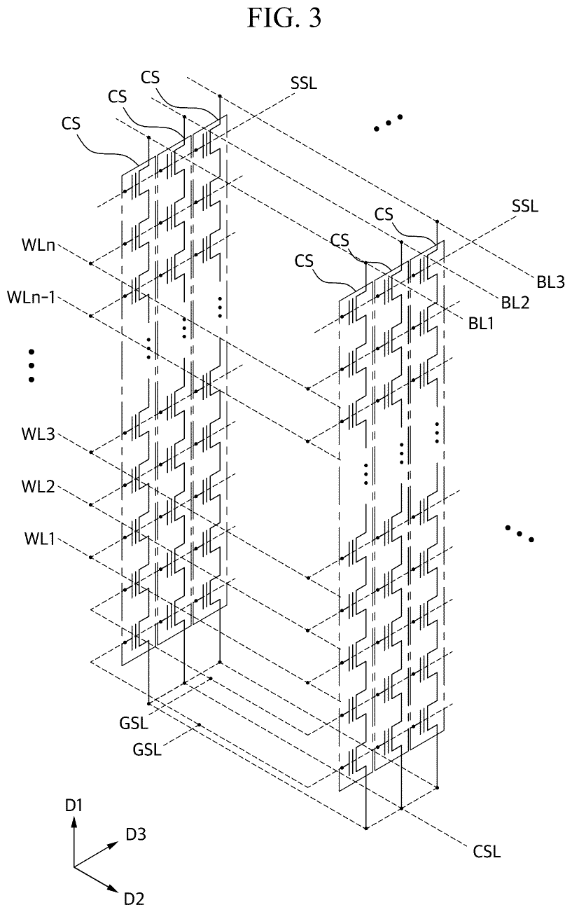

FIG. 3 is a drawing for explaining a cell array of a semiconductor device according to an example embodiment.

Referring to FIG. 3, the cell array of a semiconductor device may include a two-dimensionally arranged string array.

The string array may contain a plurality of cell strings CS connected in parallel to bit lines (bit line BL1, BL2 and BL3). Here, the plurality of cell strings CS may extend in the first direction D1 and be connected in parallel to each of the bit lines (the bit lines BL1, BL2 and BL3). Further, the plurality of cell strings CS may be commonly connected to a common source line CSL. Here, the first direction D1 may indicate the direction perpendicular to the upper surface of the substrate on which the plurality of cell strings CS are formed.

Each of the plurality of cell strings CS may include a plurality of memory cell devices (e.g., memory cells) and a plurality of ground select transistors, which are stacked in the first direction D1 and connected in series with one another. Further, each of the plurality of cell strings CS may further include a string select transistor provided between the bit lines (the bit lines BL1, BL2 and BL3) and the plurality of memory cell devices.

In an example embodiment, a semiconductor device may include string select lines SSL electrically isolated from each other. The string select lines SSL intersect the first direction D1, and may extend along the third direction D3, intersecting the second direction D2. The string select lines SSL may control the string select transistor. Here, the second direction D2 may be the direction in which the bit lines (the bit lines BL1, BL2 and BL3) extend. Further, in an example embodiment, the third direction D3 may be a direction that is orthogonal to the first direction D1 and the second direction D2.

Each of the plurality of transistors including the memory cell devices, the ground select transistors and the string select transistors may be controlled by the local lines including a plurality of word lines (WL1-WLn). For example, the plurality of ground select transistors may be controlled by a plurality of ground select lines GSL.

Specifically, the plurality of ground select lines GSL may extend in the second direction D2, and control the plurality of ground select transistors. Here, each of the plurality of ground select lines GSL may be commonly connected to a set of ground select transistors located (or positioned) at a corresponding height level with respect to the upper surface of the substrate among the plurality of ground select transistors.

Ground selection transistors positioned at corresponding height levels relative to the upper surface of the substrate may refer to elements positioned at the same height level relative to the upper surface of the substrate. Further, the ground select transistors positioned at corresponding height levels relative to the upper surface of the substrate may refer to devices that are located at the same height level with respect to the common source line CSL. Gate electrodes of the plurality of memory cell devices positioned at the same height level relative to the upper surface of the substrate or the common source line CSL may be connected in common to one of the word lines (WL1-WLn). Gate electrodes of the plurality of ground select transistors positioned at the same height level with respect to the upper surface of the substrate or the common source line CSL may be commonly connected to one of the ground select lines GSL.

In each of a plurality of cell strings CS, the ground select transistors may have a certain threshold voltage. Here, the certain threshold voltage may be set based on at least one of the characteristics of the cell strings CS and the characteristics of the ground select lines GSL. That the threshold voltage of the ground select transistors is set may indicate that the threshold voltage of the ground select transistors is programmed to either the program voltage or the erase voltage. Therefore, ground select transistors as described in this context are programmable ground select transistors. The ground select transistors are configured to be turned on in order to allow current to flow through a corresponding cell string CS, and the threshold voltage of different ground select transistors can be programmed differently from each other.

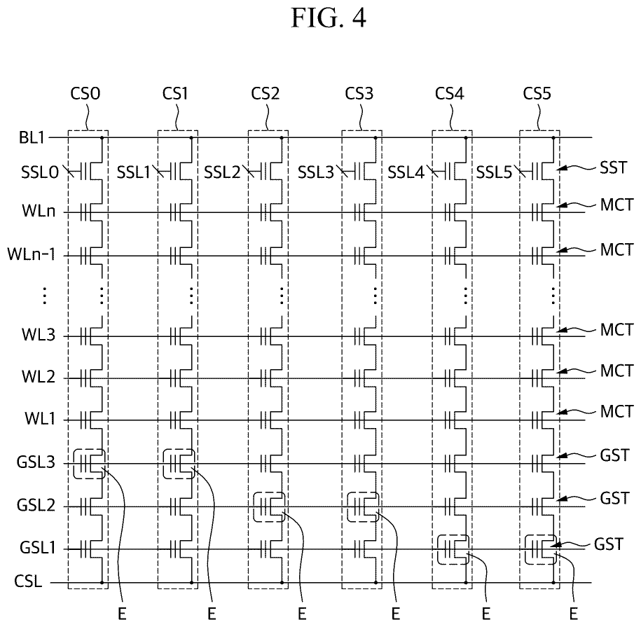

FIG. 4 is a circuit diagram illustrating a plurality of cell strings according to an example embodiment.

FIG. 4 illustrates a plurality of cell strings (a first cell string CS0 to a sixth cell string CS5) included in a semiconductor device.

In an example embodiment, the plurality of cell strings (the first cell string CS0 to the sixth cell string CS5) may be connected in parallel between one bit line BL1 and the common source line CSL. A string select transistor SST of each of the plurality of cell strings (the first cell string CS0 to the sixth cell string CS5) may be controlled by a corresponding string select line (a first string select line SSL0 to a sixth string select line SSL5).

The plurality of ground select transistors GST included in each of the plurality of cell strings (the first cell string CS0 to the sixth cell string CS5) may have respective certain threshold voltages. The ground select transistors GST marked as “E” in FIG. 4 represent the ground select transistors GST whose threshold voltage is programmed as the erase voltage.

In the example embodiment of FIG. 4, in the first cell string CS0 and a second cell string CS1, the ground select transistor GST connected to a third ground select line GSL3 may have the erase voltage as the threshold voltage, and may have a threshold voltage lower than the ground select transistors GST connected to a second ground select line GSL2 and a first ground select line GSL1, which have the program voltage as their threshold voltage.

In each of the first cell string CS0 and the second cell string CS1, the ground select transistor GST connected to the third ground select line GSL3 may be turned on by an operating voltage greater than the erase voltage and less than the program voltage. The ground select transistors GST connected to the second ground select line GSL2 and the first ground select line GSL1 may be turned on by an operating voltage that is greater than the program voltage.

Similarly, in the example embodiment of FIG. 4, in a third cell string CS2 and a fourth cell string CS3, the ground select transistor GST connected to the second ground select line GSL2 has the erase voltage as its threshold voltage, and may have a threshold voltage lower than a threshold voltage of the ground select transistors GST connected to the first ground select line GSL1 and the third ground select line GSL3, which have the program voltage as the threshold voltage. In each of the third cell string CS2 and the fourth cell string CS3, the ground select transistor GST connected to the second ground select line GSL2 may be turned on by an operating voltage that is greater than the erase voltage and less than the program voltage. The ground select transistors GST connected to the third ground select line GSL3 and the first ground select line GSL1 may be turned on by an operating voltage that is greater than the program voltage.

Further, in the example embodiment of FIG. 4, in a fifth cell string CS4 and the sixth cell string CS5, the ground select transistor GST connected to the first ground select line GSL1 has the erase voltage as its threshold voltage, and may have a threshold voltage lower than a threshold voltage of the ground select transistors GST connected to the third ground select line GSL3 and the second ground select line GSL2, which have the program voltage as the threshold voltage. In each of the fifth cell string CS4 and the sixth cell string CS5, the ground select transistor GST connected to the first ground select line GSL1 may be turned on by an operating voltage greater than the erase voltage and less than the program voltage. The ground select transistors GST connected to the second ground select line GSL2 and the third ground select line GSL3 may be turned on by an operating voltage greater than the program voltage. In all of the above examples, the program voltage is greater than the erase voltage.

Here, in an example embodiment, the ground select transistors GST of the second cell string CS1 and the third cell string CS2, which are commonly connected to the third ground select line GSL3, may operate complementarily with each other depending on the voltage applied to the third ground select line GSL3. Depending on the voltage applied to a second string select line SSL1 and a third string select line SSL2, the electrical connection between the bit line BL1 and the second cell string CS1 and the electrical connection between the bit line BL1 and the third cell string CS2 may be controlled. Also, depending on the voltage applied to the ground select lines (the ground select lines GSL1, GSL2 and GSL3), the electrical connection between the second cell string CS1 and the common source line CSL and the electrical connection between the third cell string CS2 and the common source line CSL may be controlled.

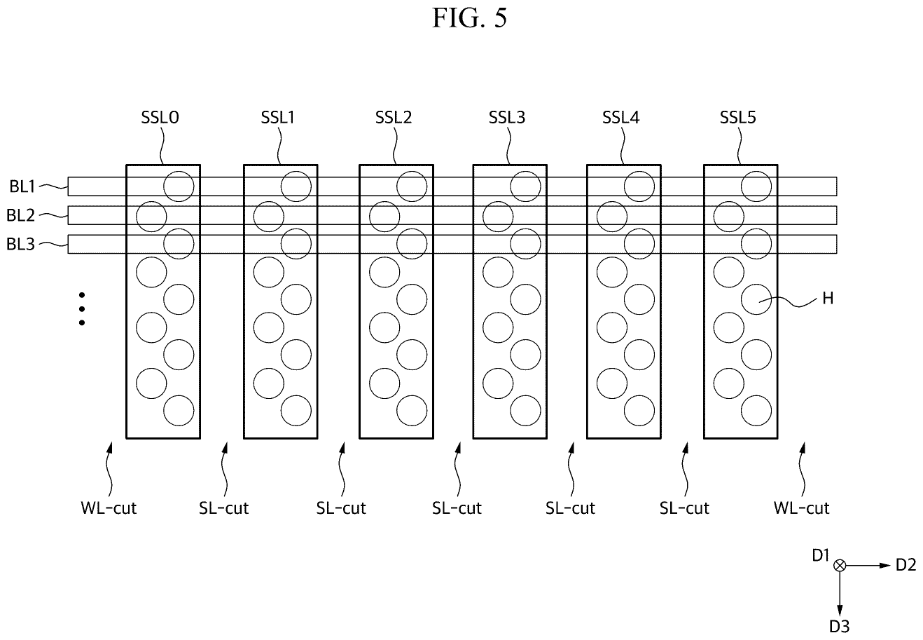

FIG. 5 is a plan view illustrating a semiconductor device according to an example embodiment.

The semiconductor device may include gate electrode structures forming local lines (the string select line SSL, the ground select line GSL and the word line WL). The gate electrode structures may be placed on the substrate. FIG. 5 illustrates the first string select line SSL0 to the sixth string select line SSL5 located at the top. However, the gate electrode structures may include the ground select lines GSL and the word lines WL. Here, the ground select line GSL may be located at the lowest layer of the gate electrode structures, and the word line WL may be placed between the ground select line GSL and the string select line (the first string select line SSL0 to the sixth string select line SSL5). The gate electrode structures may be composed of doped silicon, metals (e.g., tungsten), metal nitrides, metal silicides, and/or a combination of at least some of these. Further, the substrate may be a silicon substrate, a silicon-germanium substrate, a germanium substrate or a single crystal epitaxial layer grown on a single crystal silicon substrate.

In an example embodiment, the gate electrode structures may be cut by string select line cut regions (SL-cut) or word line cut regions (WL-cut). Referring to FIG. 5, a string array may be placed between two word line cut regions (WL-cuts) that extend in the third direction D3 and adjacent in the second direction D2. For example, a first characteristic of the cell string of the string array is a distance from one of two adjacent word line cut regions. Here, the string array may contain the first string select line SSL0 to the sixth string select line SSL5. The first string select line SSL0 to the sixth string select line SSL5 may be formed by cutting gate lines of the same height from the upper surface of the substrate by string select line cut regions (SL-cut). For convenience of explanation, FIG. 5 illustrates that six string select lines (string select lines SSL0 to SSL5) are placed between two word line cut regions (WL-cut). However, the present disclosure is not limited thereto. The number of the string select lines (the first string select line SSL0 to the sixth string select line SSL5) may vary depending on various example embodiments.

With the generational transition of NAND flash memory devices, the number of word lines WL stacked in a vertical direction with respect to the upper surface of the substrate and the number of string select lines (the first string select line SSL0 to the sixth string select line SSL5) arranged between adjacent word line cut regions (WL-cut) are increasing. As the number of stacked word lines WL increases, the memory capacity per unit region may be increased, and as the number of word line cut regions (WL-cut) decreases, that is, as the number of string select lines (the first string select line SSL0 to the sixth string select line SSL5) located between adjacent word line cut regions (WL-cut) increases, the size of the memory block may be reduced.

However, as the number of string select lines (the first string select line SSL0 to the sixth string select line SSL5) placed between adjacent word line cut regions (WL-cut) increases, channel hole skew increases between the near and far regions of the word line cut region (WL-cut) due to manufacturing process constraints. Accordingly, the closer the region is to the word line cut region, the thinner the charge storage structure becomes, and thus the erase speed skew and the program speed skew increase.

As such, in each of the plurality of transistors of the semiconductor device, deterioration may occur due to certain factors. In nonvolatile memory devices such as NAND flash memory, as repetitive read operations are performed, read disturb degradation (RDD) may occur, in which data in adjacent cells is damaged due to leakage current, etc. Further, over time, the charge stored inside the memory device may leak, causing deterioration in data retention characteristics, or when a transistor is in operation, the performance of the memory device may deteriorate due to the hot carrier injection (HCI) phenomenon.

Here, the lower the word line WL is located and closer the included cell string is to the word line cut regions (WL-cut), the more severe the deterioration of the memory cell, or the transistor.

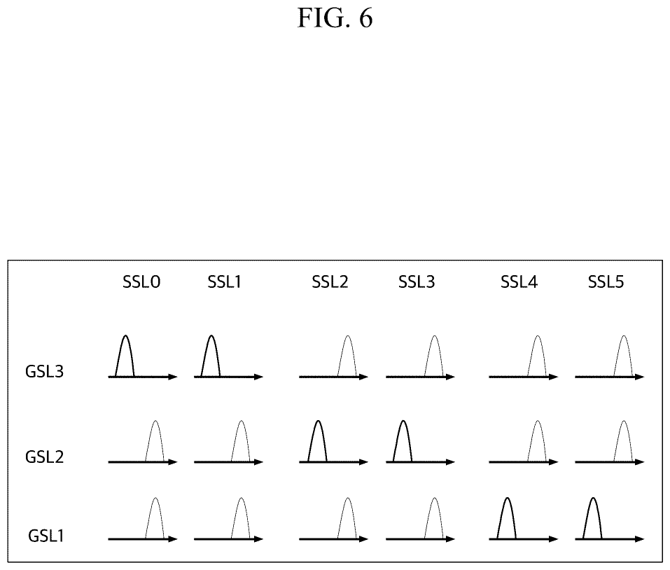

FIG. 6 to FIG. 9 are drawings for explaining a method of setting a threshold voltage of a ground select transistor according to an example embodiment.

FIG. 6 illustrates the threshold voltage of a plurality of ground select transistors having an arrangement of the erase voltage according to the example embodiment described above in FIG. 4.

When setting the erase voltage regardless of the distance from the word line cut region as in FIG. 6, the ground select transistor GST of the sixth cell string CS5 connected to the first ground select line GSL1 may have very poor performance because of the deterioration resulting from the sixth cell string CS5 being adjacent to the word line cut region in addition to GSL1 being located at the bottommost part of the cell array. Therefore, it may affect the control of the electrical connection as described with reference to FIG. 4. Accordingly, a method to set threshold voltage to compensate for transistor degradation characteristics is required.

In an example embodiment, the threshold voltage of each of the plurality of ground select transistors may be set so that the characteristics of ground select lines (the first ground select line GSL1 to the third ground select line GSL3) to which each of a plurality of ground select transistors is connected compensate for the characteristics of cell strings in which each of a plurality of ground select transistors is included.

Below, for convenience of explanation, example embodiments are described based on the fact that a cell string (the first cell string CS0 to the sixth cell string CS5) in which each of a plurality of ground select transistors is included corresponds to a string select line (the first string select line SSL0 to the sixth string select line SSL5). For example, SSL0 indicates each of the multiple first cell strings connected to the first string select line SSL0. Likewise, the second string select line SSL1 to the sixth string select line SSL5 refers to each of the second to sixth cell strings connected to the second string select line SSL1 to the sixth string select line SSL5. Accordingly, below, the first to sixth cell strings are described to correspond to the first string select line SSL0 to the sixth string select line SSL5.

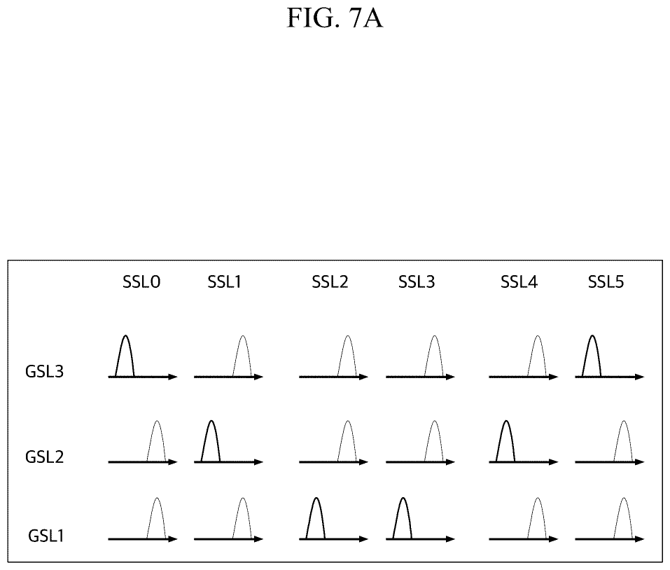

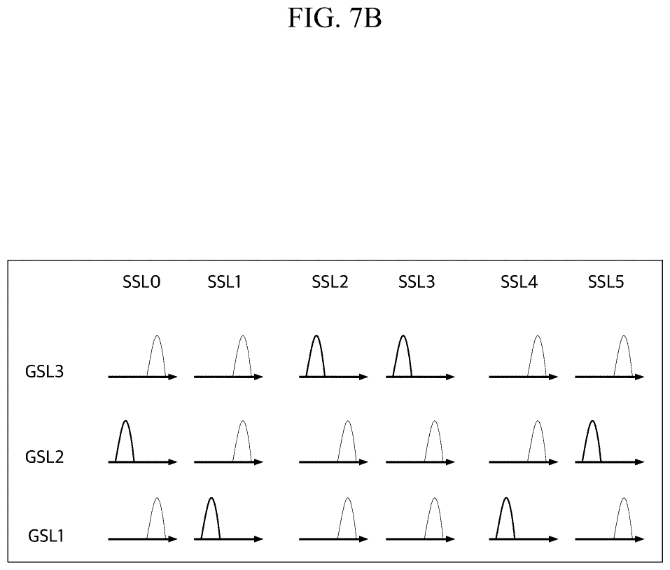

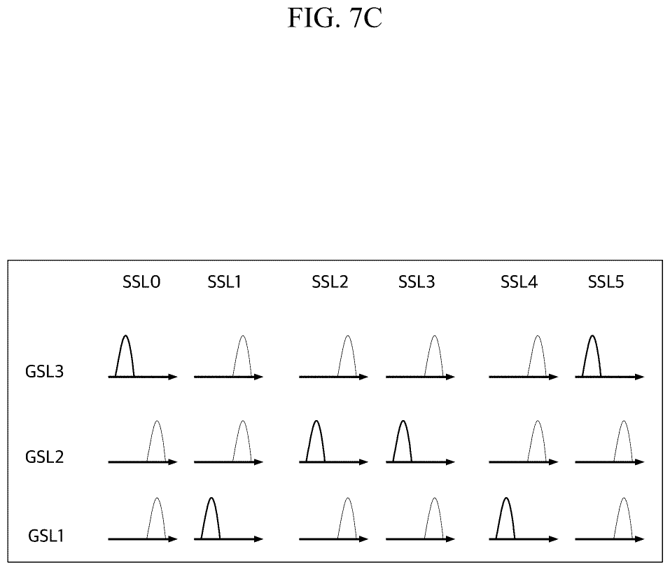

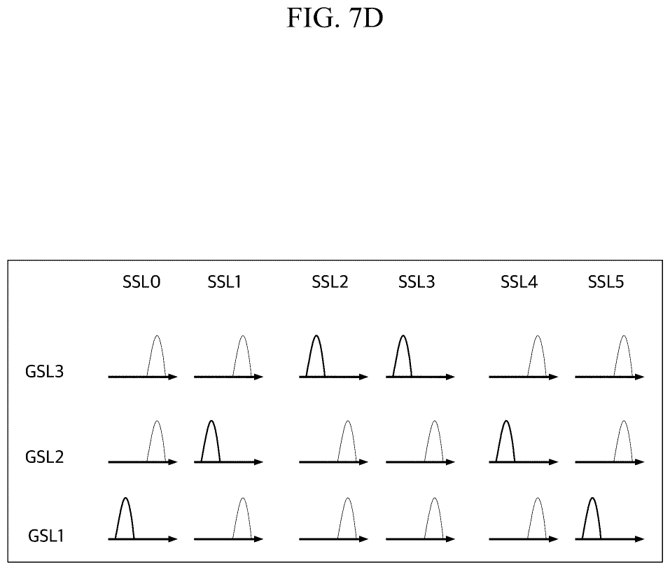

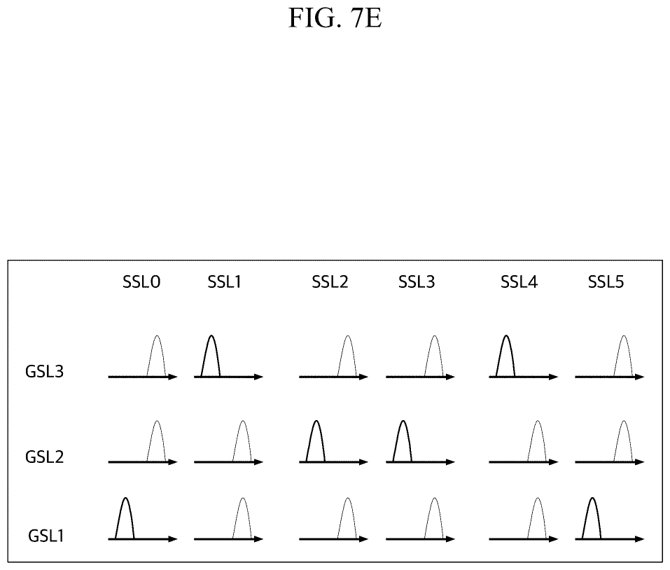

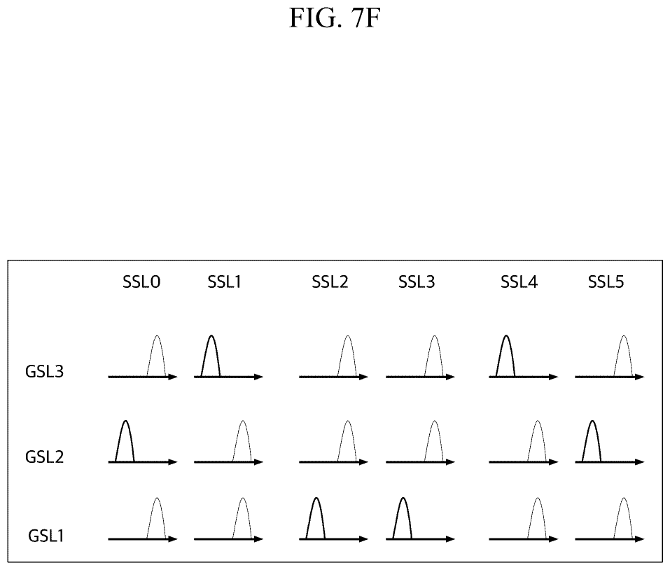

Referring to FIG. 7A, in an example embodiment, a threshold voltage of each of a plurality of ground select transistors may be set based on the first characteristic of a cell string (CS0-CS5), each of which contains a plurality of ground select transistors.

In an example embodiment, a plurality of ground select transistors contained in multiple cell strings (CS0-CS5) may be classified into two or more groups based on a first characteristic. Here, two or more ground select transistors included in cell strings having the same first characteristic may be grouped into the same group. Specifically, when the first characteristic is determined based on the distance from the word line cut region (for example, in case the first characteristic is deterioration of ground select transistor according to a distance from a word line cut region), the ground select transistors of the first cell string (CS0) and the sixth cell string (CS5) may be grouped into the same group, the ground select transistors of the second cell string (CS1) and the fifth cell string (CS4) may be grouped into the same group, and the ground select transistors of the third cell string (CS2) and the fourth cell string (CS3) may be grouped into the same group.

In an example embodiment, the multiple groups may include an inner cell string group and an outer cell string group distinguished by their distance from the word line cut region. Here, the outer cell string group may be closer to the word line cut region than the inner cell string group. In an example embodiment, in FIG. 7A, ground select transistors included in the first cell string (CS0) and sixth cell string (CS5) may be classified into the outer cell string group, and ground select transistors included in the third cell string (CS2) and fourth cell string (CS3) may be classified into the inner cell string group. The ground select transistors included in the second cell string (CS1) and the fifth cell string (CS4) may be classified into the inner cell string group or the outer cell string group, or may be classified into other groups that do not fall into the category of the inner cell string group and the outer cell string group (e.g., a middle cell string group).

When a plurality of ground select transistors included in multiple cell strings (CS0-CS5) are classified into multiple groups based on the first characteristic, the plurality of ground select transistors may be grouped to be symmetrical in the second direction (or be symmetrical with respect to the third direction D3) based on the center of the string array. For example, in FIG. 7A, each of the first ground select line GSL1 to the third ground select line GSL3 are symmetrical in the direction of extension, based on the distance from a midway line between the third string select line SSL2 and a fourth string select line SSL3.

In an example embodiment, a threshold voltage of each of the plurality of ground select transistors may be set based on a second characteristic of the ground select line (the first ground select line GSL1 to the third ground select line GSL3) to which each of a plurality of ground select transistors is connected. In an example embodiment, the second characteristic of the ground select line (the first ground select line GSL1 to the third ground select line GSL3) may be determined based on the distance from the upper surface of the substrate. As described above, the closer a word line is to the bottom, the more severe the deterioration of the memory cells may be. Therefore, in the example embodiment of FIG. 7A, deterioration of the ground select transistors of the first ground select line GSL1, located at the bottom, may be the most severe. Accordingly, each of the plurality of ground select transistors may have a threshold voltage that is set based on the degradation characteristics of the ground select lines (the first ground select line GSL1 to the third ground select line GSL3) according to the distance from the upper surface of the substrate.

Specifically, the plurality of ground select lines (the first ground select line GSL1 to the third ground select line GSL3) may include an upper ground select line and a lower ground select line. Here, the lower ground select line may indicate a ground select line located at a lower height level relative to the upper surface of the substrate than the upper ground select line. For example, in the example embodiment of FIG. 7A, the first ground select line GSL1 may correspond to the lower ground select line, and the third ground select line GSL3 may correspond to the upper ground select line.

Here, in an example embodiment, for two or more ground select transistors in the inner cell string group connected to the lower ground select line, a set threshold voltage may be the same threshold voltage as a threshold voltage of two or more ground select transistors in the outer cell string group connected to the upper ground select line. In an example, setting the same threshold voltage for two ground select transistors may result in the two ground select transistors having an identical state (e.g., a program state or an erase state). In an example embodiment, referring to FIG. 7A, it is identified that the same erase voltage is set to the ground select transistors of the third and fourth cell strings (CS2, CS3) connected to the first ground select line GSL1, and the same erase voltage is set to the ground select transistors of the first and sixth cell strings (CS0, CS5) connected to the third ground select line GSL3. Similarly, it may be identified that the same erase voltage is set to the ground select transistors of the second and fifth cell strings (CS1, CS4) connected to the second ground select line GSL2.

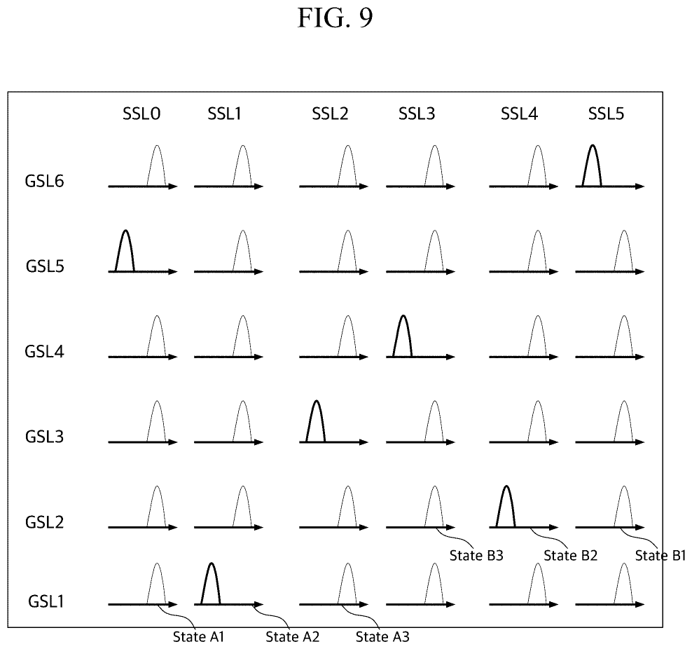

In an example embodiment, the same threshold voltage may be set for two or more ground select transistors in the same group connected to the same ground select line. In an example embodiment, referring to FIG. 7A, it is identified that the same erase voltage is set to the ground select transistors in the inner cell string group connected to the first ground select line GSL1, and the same program voltage is set to the ground select transistors connected to the first ground select line GSL1 and included in the outer cell string group and the second and fifth cell strings (CS1, CS4). However, for two or more ground select transistors in the same group connected to the same ground select line, threshold voltages that are different may be set. Example embodiments with regard thereto are described in detail with reference to FIG. 9.

As such, a threshold voltage of each of the plurality of ground select transistors may be set so that the second characteristic of the ground select line (the first ground select line GSL1 to the third ground select line GSL3) that each of a plurality of ground select transistors is connected to compensates for the first characteristic of cell strings (CS0-CS5) that each of the plurality of ground select transistors is included. Accordingly, uniform degradation through the cell array may be more likely.

FIG. 7B to FIG. 7F illustrate various example embodiments for which in a memory block consisting of three ground select lines (the first ground select line GSL1 to the third ground select line GSL3) and six string select lines (the first string select line SSL0 to the sixth string select line SSL5), a threshold voltage of the plurality of ground select transistors is set. Due to changes in process and design, there may be improvement with respect to the degradation characteristics of the above-described transistors in the outer cell string group near the lower word line and the word line cut region. Therefore, the plurality of ground select transistors included in the plurality of cell strings (CS0-CS5) may be grouped according to a first characteristic determined based on the distance from the word line cut region, and the erase voltage or the program voltage is set to the plurality of ground select transistors that are grouped based on at least one of the first characteristic and the second characteristic that is determined based on and the distance from the upper surface of the substrate; however, the present disclosure is not limited to what is illustrated in FIG. 7A. Therefore, the present disclosure may be implemented as the various example embodiments illustrated in FIG. 7B to FIG. 7F.

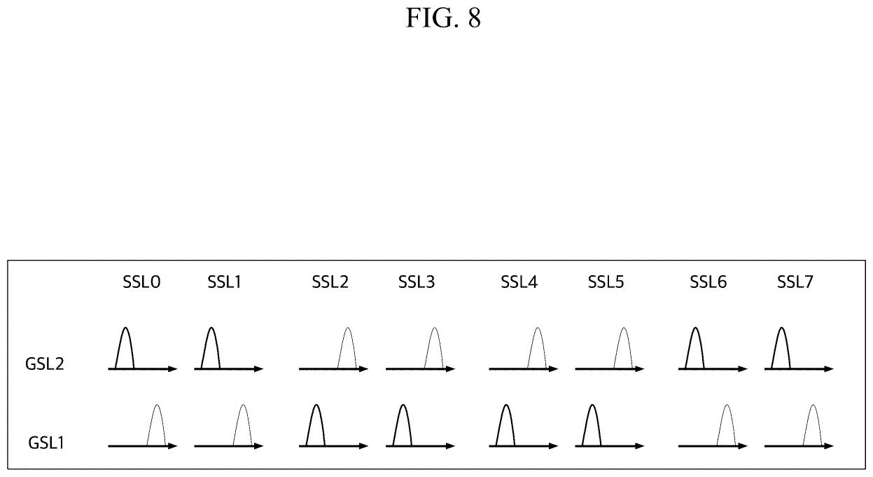

FIG. 8 illustrates an example embodiment for which in a memory block consisting of two ground select lines (the first ground select line GSL1 and the second ground select line GSL2) and eight string select lines (the first string select line SSL0 to an eight string select line SSL7), a threshold voltage of the plurality of ground select transistors is set.

As illustrated in FIG. 8, the same threshold voltage may be set even for ground select transistors in different groups that are connected to the same ground select line. For example, when ground select transistors of the third and sixth cell strings (CS2, CS5) are grouped into the same group and ground select transistors of the fourth and fifth cell strings (CS3, CS4) are grouped into the same group, the same erase voltage is set to all ground select transistors of the third to sixth cell strings (CS2-CS5) connected to the first ground select line GSL1. However, as can be seen from FIG. 8, the threshold voltage is set correlatively with the distance from the word line cut region or the distance from an upper surface of the substrate; the plurality of ground select transistors are grouped based on the first characteristic and/or the second characteristic, and the threshold voltage is set to compensate for the degradation characteristic of each of the plurality of ground select transistors.

The number of ground select line (the first ground select line GSL1 and the second ground select line GSL2) of a memory block consisting of eight string select lines (the first string select line SSL0 to the eight string select line SSL7) is not limited to two, and as the number of ground select lines (the first ground select line GSL1 and the second ground select line GSL2) increases, various example embodiments may be applied. For example, the same threshold voltage may be set for ground select transistors connected to the same ground select line in some different groups, as shown in FIG. 8, and different threshold voltages may be set for others of the different groups based on the first characteristic and/or the second characteristic. Also, as will be described later with reference to FIG. 9, the same threshold voltage may be set for ground select transistors in the same group located on adjacent ground select lines. However, in the various example embodiments described above, a threshold voltage may be set in order for a plurality of ground select transistors to be grouped based on the first characteristic and/or the second characteristic, and for the degradation characteristics of each of a plurality of ground select transistors to be compensated.

FIG. 9 illustrates an example embodiment for which in a memory block consisting of six ground select lines (the first ground select line GSL1 to a sixth ground select line GSL6) and six string select lines (the first string select line SSL0 to the sixth string select line SSL5), a threshold voltage of the plurality of ground select transistors is set. As illustrated in FIG. 9, when the same threshold voltage cannot be set to ground select transistors in the same group connected to any ground select line due to the structure, or when the same threshold voltage is not set for ground select transistors connected to any ground select line in the same group due to various factors, the same threshold voltage may be set for ground select transistors located on adjacent ground select lines in the same group. In other words, in an example embodiment, for ground select transistors connected to a specific ground select line in a specific group, the same threshold voltage may be set as that of ground select transistors connected to a ground select line that is adjacent to the specific ground select line in the specific group.

Described is an example embodiment illustrated in FIG. 9 where the ground select transistors of the first and sixth cell strings (CS0, CS5) are grouped into a first group, the ground select transistors of the second and fifth cell strings (CS1, CS4) are grouped into a second group, and the ground select transistors of third and fourth cell strings (CS2, CS3) are grouped into a third group.

For f ground select transistors connected to the first ground select line GSL1 in the second group, the set threshold voltage is the same erase voltage as the threshold voltage of ground select transistors connected to the second ground select line GSL2 adjacent to the first ground select line GSL1 in the second group. Likewise, for the ground select transistors in the first and third groups connected to the first ground select line GSL1, set threshold voltage is the same program voltage as the threshold voltage of ground select transistors in the first and third groups connected to the second ground select line GSL2 adjacent to the first ground select line GSL1. Here, in this example embodiment, the erase voltage may be set to ground select transistors in the second group connected to the first ground select line GSL1 and the second ground select line GSL2, or the erase voltage and the program voltage may be set to different groups depending on the various example embodiments.

For the ground select transistors in the third group connected to the third ground select line GSL3, the set threshold voltage is the same erase voltage as the threshold voltage of ground select transistors in the third group connected to a fourth ground select line GSL4 adjacent to the third ground select line GSL3. Likewise, for the ground select transistors in the first group and the second group connected to the third ground select line GSL3, set threshold voltage is the same program voltage as the threshold voltage of the ground select transistors in the first and second groups connected to the fourth ground select line GSL4 adjacent to the third ground select line GSL3. Here, in the example embodiment, the erase voltage may be set to ground select transistors in the third group connected to the third ground select line GSL3 and the fourth ground select line GSL4, but the erase voltage and the program voltage may be set to different groups depending on the various example embodiments. Further, even though the example embodiment describes that the ground select line adjacent to the third ground select line GSL3 is the fourth ground select line GSL4, the ground select line adjacent to the third ground select line GSL3 may be the second ground select line GSL2.

Likewise, above descriptions with regard to the example embodiment may be identically applied to the example embodiment in which the same erase voltage is set to ground select transistors in the first group connected to a fifth ground select line GSL5 and ground select transistors in the first group connected to the sixth ground select line GSL6.

To describe some of the above embodiments in a different way, ground select transistors in certain groups may have certain characteristics. For example, for a first array of ground select transistors between two word line cut regions, a first group of ground select transistors may include a first set of ground select transistors most closely adjacent to the first word line cut region and a second set of ground select transistors most closely adjacent to the second word line cut region. These two sets of ground select transistors in some embodiments, as can be seen in FIGS. 7A-7F, may have the same states (e.g., program states or the erase states) based on their set threshold voltages. For example, in FIG. 7A, the first set of ground select transistors of the first cell string CS0 connected to the ground select lines GSL1, GSL2, and GSL3 may have the same states as the sixth set of ground select transistors of the sixth cell string CS5 connected to the ground select lines GSL1, GSL2, and GSL3, wherein the first set and sixth set form a group of ground select transistors. The same may apply for the second set of ground select transistors of the second cell string CS1 connected to the ground select lines GSL1, GSL2, and GSL3and fifth set of ground select transistors of the fifth cell string CS4 connected to the ground select lines GSL1, GSL2, and GSL3, and for the third set of ground select transistors of the third cell string CS2 connected to the ground select lines GSL1, GSL2, and GSL3 and fourth set of ground select transistors of the fourth cell string CS3 connected to the ground select lines GSL1, GSL2, and GSL3. The characteristic for these different groups (which can be described as a first characteristic, or more specifically as a horizontal location characteristic) is a distance (e.g., horizontal distance) from a word line cut region. Therefore, in one embodiment, for a given ground select line (e.g., GSL1 as one example), a threshold voltage for any two ground select transistors having the same horizontal location characteristic can be set to result in the same state (e.g., erase state or program state).

Another characteristic that can describe the various ground select transistors between two word line cut regions is a vertical distance from a surface (e.g., the upper surface) of the semiconductor substrate or a vertical distance from a common source line (CSL). This characteristic, which can be described as a second characteristic, or a vertical location characteristic, can be used to determine what state to program the ground select transistors to. For example, typically, deterioration may occur more for transistors closer to the surface of the substrate than for transistors further away. Accordingly, to compensate for this, different threshold voltages resulting in different program states can be set for ground select transistors closer to the substrate than ground select transistors further away.

In some cases, both a first characteristic (e.g., horizontal location characteristic) and a second characteristic (e.g., vertical location characteristic) can be used to determine which state (e.g., erase or program) the various ground select transistors should be set to. For example, as shown in FIG. 7A, because both the vertical distance from the substrate and the horizontal distance from the word line cut region may affect deterioration of ground select transistors, in some embodiments in a somewhat similar way, ground select transistors closest to the substrate but furthest from the word line cut regions (e.g., the ground select transistor connected to first ground select line GSL1 and included in the third cell string CS2, and the ground select transistor connected to first ground select line GSL1 and included in the fourth cell string CS3) may be set to the erase state, along with ground select transistors furthest from the substrate but closest to the word line cut regions (e.g., the ground select transistor connected to third ground select line GSL3 and included in the first cell string CS0, and the ground select transistor connected to third ground select line GSL3 and included in the sixth cell string CS5), and also along with intermediate ground select transistors halfway between these two extremes.

As shown in the various examples of FIGS. 7A to 7F, in some embodiments, states of ground select transistors with respect to a center point or center line between the first string select line (e.g., SSL0) and the last string select line (e.g., sixth string select line SSL5) may be symmetrically set. In this case, for each ground select line, the states of ground select transistors with respect to a center point or center line between the first string select line and a last string select line are symmetrical.

As shown in FIG. 9, however, in some embodiments, rather than the states of the ground select transistors connected to a single ground select line being symmetrical about a center point or center line, the states on one side of the center point or center line for first ground select transistors connected to a first ground select line can be symmetrical to states on the opposite side of the center point or center line for second ground select transistors connected to a second ground select line adjacent to the first ground select line. This can be seen, for example, by comparing states A1, A2, and A3 in FIG. 9 to respective states B1, B2, and B3, for example.

The example embodiments described above with reference to FIG. 7A to FIG. 9 are mere example embodiments, and the number of ground select lines is not limited to 3, 2 and 6, neither is the number of cell strings limited to 6, 8 and 9. Also, it should be noted that the indication of the threshold voltages as either having an erase state or a program state in the various figures uses a voltage distribution diagram to show the range of threshold voltages that the particular transistor/memory cell can be set to result in an erase state or a program state.

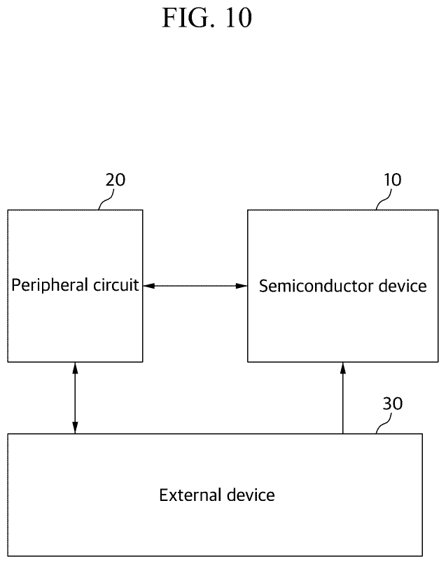

FIG. 10 is a diagram illustrating a data storage system according to an example embodiment.

Referring to FIG. 10, the data storage system may include a semiconductor substrate (not illustrated), the semiconductor device 10 on the semiconductor substrate (not illustrated) and the peripheral circuit 20 electrically connected to the semiconductor device 10 and performing a program operation for the semiconductor device 10.

In an example embodiment, the semiconductor device 10 may include a plurality of memory cell devices and a plurality of ground select transistors that are included in each of multiple cell strings connected in parallel to the bit line, are stacked in the first direction, and are connected in series to each other. Further, in an example embodiment, the semiconductor device 10 may include a plurality of word lines extending in a second direction intersecting the first direction and controlling a plurality of memory cell devices, and a plurality of ground select lines extending in the second direction and controlling the plurality of ground select transistor. Here, each of the plurality of ground select lines may be commonly connected to a ground select transistor that is located at a corresponding height level with respect to the upper surface of the substrate among the plurality of ground select transistors. Therefore, each of the plurality of ground select lines may be commonly connected to a ground select transistor located at the same height level with respect to the upper surface of the substrate among the plurality of ground select transistors. Accordingly, among the plurality of ground select transistors, ground select transistors located at the same height level relative to the upper surface of the substrate may share one ground select line.

In an example embodiment, the plurality of memory cell devices are included in the main word line region that stores data, and the plurality of ground select transistors may be included in a sub word line region that controls access to the main word line region according to a threshold voltage that is set for each of the plurality of ground select transistors. The threshold voltage that is set for each of the plurality of ground select transistors is as described above with reference to FIG. 1 to FIG. 9. Here, both the main word line region and the sub word line region may be formed from a plurality of word lines. For example, the plurality of ground select lines may be formed using at least some of the plurality of word lines, and the word line and ground select line may be functionally separate but structurally identical.

In an example embodiment, the peripheral circuit 20 may program the threshold voltage of each of a plurality of ground select transistors based on the first characteristic of the ground select line to which each of the plurality of ground select transistors is connected. Therefore, the peripheral circuit 20 may code a plurality of ground select transistors of the semiconductor device 10 to have the above-described threshold voltages, for example, by the peripheral circuit 20 generating and/or sending commands to the plurality of ground select transistors to program them.

Alternatively, in an example embodiment, the data storage system may further include an external device 30. The external device 30 may code (e.g., generate and send commands to) a plurality of ground select transistors of the semiconductor device 10 to have the above-described threshold voltages, and the external device 30 may control the peripheral circuit 20 or the semiconductor device 10 in order for a plurality of ground select transistors of the coded ground select line to be turned on in response to the same voltage, and the others to be turned off.

It would be understood that the example embodiments in which a threshold voltage of the plurality of ground select transistors is set with reference to FIG. 1 to FIG. 9 may be implemented by being coded by the peripheral circuit 20 or the eternal device 30.

In an example embodiment, the peripheral circuit 20 and the eternal device 30 may include a host device such as processor (not illustrated) and a memory (not illustrated).

The memory (not illustrated) may be hardware that stores various data processed within the peripheral circuit 20 or the external device 30, and may store programs for processing and controlling the processor (not illustrated).

The memory (not illustrated) may include random access memory (RAM), such as dynamic random access memory (DRAM), static random access memory (SRAM), read-only memory (ROM), electrically erasable programmable read-only memory (EEPROM), CD-ROM, Blu-ray or other optical disk storage, hard disk drive (HDD), solid state drive (SSD) or flash memory.

The processor (not illustrated) controls the overall operation of the peripheral circuit 20 or the external device 30. For example, by executing programs stored in memory (not illustrated), the processor (not illustrated) may control the input unit (not illustrated), display (not illustrated), communication unit (not illustrated), memory (not illustrated), etc., which are further included in the peripheral circuit 20 or the external device 30. By executing programs stored in the memory (not illustrated), the processor (not illustrated) may control the operation of the peripheral circuit 20 or the external device 30.

The processor (not illustrated) may control at least some of the operations for implementing the devices described with reference to FIG. 1 to FIG. 9, such as setting the threshold voltages of the various ground select transistors. This may be implemented based on different characteristics of the transistors, such as first and second characteristics (e.g., which may be different types of location characteristics in some embodiments, but are not limited thereto). The threshold voltages may be set, for example by a host or controller, when the semiconductor device is initially operated or manufactured to remain the same throughout the lifetime of the semiconductor device, or may be dynamically set, for example by the host or controller, during operation and/or based on an updated status of the different transistors of the semiconductor device.

The processor (not illustrated) may be implemented using at least one of application specific integrated circuits (ASICs), digital signal processors (DSPs), digital signal processing devices (DSPDs), programmable logic devices (PLDs), field programmable gate arrays (FPGAs), controllers, micro-controllers, microprocessors, and other electrical units for performing functions.

In an example embodiment, the peripheral circuit 20 or the external device 30 may be a host, such as a server. The server may be implemented as a computer device or multiple computer devices that communicate over a network to provide commands, codes, files, content, services, etc. The server may receive data necessary to program a threshold voltage of a plurality of ground select transistors of the semiconductor device 10, and may program threshold voltages of a plurality of ground select transistors of the semiconductor device 10 based on the received data.

In some embodiments, the peripheral circuit 20 or the external device 30 may further include a communication part (not illustrated). The communication part (not illustrated) may include one or more components that enable wired/wireless communication with an external server or external device. For example, the communication part (not illustrated) may include at least one of a short-range communication part (not illustrated), a mobile communication part (not illustrated), and a broadcast receiver (not illustrated). In an example embodiment, the communications part (not illustrated) may receive data for programming a threshold voltage of a plurality of ground select transistors of the semiconductor device 10.

The peripheral circuit 20 or the external device 30 according to the above described example embodiments may include a processor, a memory for storing and executing program data, a permanent storage such as a disk drive, and/or a user interface device such as a communication port, a touch panel, a key and/or a button that communicates with the external device. Methods implemented as software modules or algorithms may be stored in a non-transitory computer-readable recording medium as computer-readable codes or program instructions executable on the processor. Here, the computer-readable recording medium may include a magnetic storage medium (for example, ROMs, RAMs, floppy disks and hard disks) and an optically readable medium (for example, CD-ROMs and DVDs). The computer-readable recording medium may be distributed among network-connected computer systems, so that the computer-readable codes may be stored and executed in a distributed manner. The medium may be readable by a computer, stored in a memory, and executed on a processer.

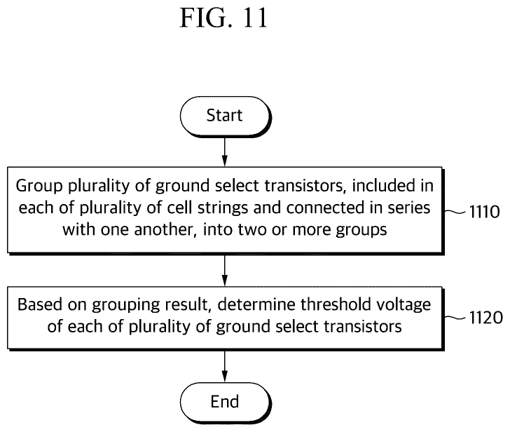

FIG. 11 is a flowchart of a programming method for a semiconductor device according to an example embodiment.

Each operation illustrated in FIG. 11 may be performed in the peripheral circuit or the external device (hereinafter referred to as “device”). Specifically, each operation of FIG. 11 may be performed by a processor included in the device.

In operation 1110, the device may group a plurality of ground select transistors, included in each of a plurality of cell strings and connected in series with one another, into two or more groups. Each group may include two or more sets of ground select transistors. In an example, each set of ground select transistors may include a plurality of ground select transistors connected to a plurality of ground select lines in one cell string.

In an example embodiment, the device may group a plurality of ground select transistors contained in a plurality of cell strings into two or more groups based on a first characteristic (e.g., a first location characteristic) of cell strings that each of a plurality of ground select transistors is included.

In an example embodiment, by the device classifying a plurality of ground select transistors contained in multiple cell strings into multiple groups including an inner cell string group and an outer cell string group that is closer to the word line cut region than the inner cell string group, grouping may be performed symmetrically in a particular direction based on the center of the string array. In an example, the states of the plurality of ground select transistors of the plurality of cell strings grouped into the inner cell string group and the outer cell string group may be symmetrical in a second direction based on a center of the string array comprising the plurality of cell strings.

In operation 1120, based on the grouping result, the device may determine a threshold voltage (or a state) of each of the plurality of ground select transistors.

In an example embodiment, the device may determine a threshold voltage of the plurality of ground select transistors based on the first characteristic. Further, the device may additionally or alternatively set the threshold voltage based on a second characteristic (e.g., a second location characteristic) of a plurality of ground select lines to which each of the plurality of ground select transistors is connected.

In an example embodiment, the device may determine a threshold voltage such that the second characteristic of the plurality of ground select lines to which each of the plurality of ground select transistors is connected compensates for the first characteristic of the cell string that each of the plurality of ground select transistors is included.

In an example embodiment, the device may set different threshold voltages for ground select transistors connected to the same ground select line in two or more different groups. Further, the device may set the same threshold voltage to two or more ground select transistors in the same group connected to the same ground select line.

In an example embodiment, the plurality of ground select lines may include an upper ground select line and a lower ground select line located at a lower height level with respect to the upper surface of the substrate than the upper ground select line. Here, for two or more ground select transistors in the inner cell string group connected to the lower ground select line, the device may set the same threshold voltage as the threshold voltage of two or more ground select transistors in the outer cell string group connected to the upper ground select line.

In an example embodiment, for ground select transistors connected to the first ground select line in the first group, the device may set the same threshold voltage as the threshold voltage of ground select transistors connected to the second ground select line adjacent to the first ground select line in the first group. In an example, the device may program at least a portion of the plurality of ground select transistors to a determined threshold voltage (or a state).

Some of the features of the example embodiments may be represented by functional block elements and various processing operations. The functional blocks may be implemented in any number of hardware and/or software configurations that perform specific functions. For example, an example embodiment may adopt integrated circuit configurations, such as memory, processing, logic and/or look-up table, that may execute various functions by the control of one or more microprocessors or other control devices. Similar to that elements may be implemented as software programming or software elements, the example embodiments may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

The above-described example embodiments are merely examples, and other embodiments may be implemented within the scope of the attached claims.

What is claimed is:

1. A semiconductor device comprising:
a string array comprising a plurality of cell strings that are connected in parallel to a bit line;
a plurality of ground select transistors that are included in each of the plurality of cell strings, stacked in a first direction and connected in series with each other; and
a plurality of ground select lines that extend in a second direction intersecting the first direction and are configured to control the plurality of ground select transistors,
wherein each of the plurality of ground select lines is commonly connected to a ground select transistor located at a corresponding height level with respect to an upper surface of a substrate among the plurality of ground select transistors, and
wherein each particular ground select transistor of the plurality of ground select transistors has a particular threshold voltage that depends on a first characteristic of the cell string in which of the particular ground select transistor is included.

2. The semiconductor device of claim 1, wherein the string array is placed between two adjacent word line cut regions that each extend in the first direction, and
wherein the first characteristic is a distance from at least one of the two adjacent word line cut regions.

3. The semiconductor device of claim 2, wherein the threshold voltage of each particular ground select transistor of the plurality of ground select transistors also depends on a second characteristic of the ground select line to which the particular ground select transistor is connected.

4. The semiconductor device of claim 3, wherein the second characteristic is a distance from the upper surface of the substrate.

5. The semiconductor device of claim 3, wherein the second characteristic of the ground select line to which each of the plurality of ground select transistors is connected compensates for the first characteristic of the cell strings including each of the ground select transistors.

6. The semiconductor device of claim 3, wherein the plurality of ground select transistors are grouped into two or more groups based on the first characteristic.

7. The semiconductor device of claim 6, wherein two or more ground select transistors included in a cell string having an identical first characteristic are grouped into an identical group.

8. The semiconductor device of claim 6, wherein a threshold voltage resulting in an identical state is set for two or more ground select transistors in an identical group that are connected to an identical ground select line.

9. The semiconductor device of claim 6, wherein the plurality of ground select transistors are grouped into a plurality of groups comprising an inner cell string group and an outer cell string group that is closer to a word line cut region than the inner cell string group, and are grouped symmetrically in the second direction based on a center of the string array.

10. The semiconductor device of claim 9, wherein the plurality of ground select lines comprise an upper ground select line and a lower ground select line located at a lower height level with respect to the upper surface of the substrate than the upper ground select line, and
wherein, for two or more ground select transistors in an inner cell string group that are connected to the lower ground select line, the set threshold voltage results in a state that is same as a state of two or more ground select transistors in the outer cell string group that are connected to the upper ground select line.

11. The semiconductor device of claim 6, wherein, for a ground select transistor in a first group connected to a first ground select line, the set threshold voltage results in a state that is same as a state of the ground select transistor in the first group that are connected to a second ground select line adjacent to the first ground select line.

12. A programming method of a semiconductor device, the programming method comprising:
grouping a plurality of ground select transistors included in a plurality of cell strings and forming sets of ground select transistors connected in series with each other into two or more groups;
determining a state to which to set each of the plurality of ground select transistors based on a result of the grouping,
wherein the determining comprises determining the state of each of the plurality of ground select transistors based on a first characteristic of the cell strings into which each of the plurality of ground select transistors is included; and
programming at least a portion of the plurality of ground select transistors to result in the determined states.

13. The programming method of the semiconductor device of claim 12, wherein the determining of the state to which to set each of the plurality of ground select transistors is additionally based on a second characteristic of ground select lines into which each of the plurality of ground select transistors is connected.

14. The programming method of the semiconductor device of claim 13, wherein in the determining of the state to which to set each of the plurality of ground select transistors, the second characteristic of the ground select lines into which each of the plurality of ground select transistors is connected to compensates for the first characteristic of the cell strings into which each of the plurality of ground select transistors is included.

15. The programming method of the semiconductor device of claim 13, wherein grouping comprises grouping the plurality of ground select transistors of the plurality of cell strings into the two or more groups based on the first characteristic.

16. The programming method of the semiconductor device of claim 15, wherein the programming comprises setting an identical state to two or more ground select transistors in an identical group that are connected to an identical ground select line.

17. The programming method of the semiconductor device of claim 15, wherein grouping the plurality of ground select transistors of the plurality of cell strings into the two or more groups comprises,
grouping the plurality of ground select transistors into a plurality of groups comprising an inner cell string group and an outer cell string group that is closer to a word line cut region than the inner cell string group, so that the states of the plurality of ground select transistors are symmetrical in a second direction based on a center of a string array comprising the plurality of cell strings.

18. The programming method of the semiconductor device of claim 17, wherein the plurality of ground select lines comprise an upper ground select line and a lower ground select line located at a lower height level with respect to an upper surface of a substrate than the upper ground select line, and
wherein programming comprises, for two or more ground select transistors in the inner cell string group that are connected to the lower ground select line, setting a state that is same as a state of two or more ground select transistors in the outer cell string group that are connected to the upper ground select line.

19. The programming method of the semiconductor device of claim 15, wherein programming comprises, for a ground select transistor in a first group connected to a first ground select line, setting a state that is the same as a state of a ground select transistor in the first group that is connected to a second select line adjacent to the first ground select line.

20. A data storage system comprising:
a substrate;
a semiconductor device on the substrate; and
a peripheral circuit that is electrically connected to the semiconductor device and configured to perform a program operation for the semiconductor device,
wherein the semiconductor device comprises:
a plurality of memory cell devices and a plurality of ground select transistors that are included in each of a plurality of cell strings, and which that are connected in parallel to a bit line, stacked in a first direction, and connected in series with each other;
a plurality of word lines that extend in a second direction intersecting the first direction and are configured to control the plurality of memory cell devices; and
a plurality of ground select lines that extend in the second direction and are configured to control the plurality of ground select transistors,
wherein the plurality of memory cell devices are included in a main word line region configured to store data,
wherein the plurality of ground select transistors are included in a sub word line region that is configured to control access to the main word line region according to a threshold voltage that is set for each ground select transistor,
wherein each of the plurality of ground select lines is commonly connected to a set of ground select transistors located at a corresponding height level with respect to an upper surface of a substrate among the plurality of ground select transistors, and
wherein the peripheral circuit is configured to program a threshold voltage of each of the plurality of ground select transistors based on which first ground select line each of the plurality of ground select transistors is connected to.
